(19) United States
(12) Patent Application Publication
(10) Pub. No.: US 2005/0249314 A1
(43) Pub. Date: Nov. 10, 2005

(54) Method and circuit arrangement for deciding a symbol in the complex phase space of a quadrature modulation method

(76) Inventor: Christian Bock, Freiburg (DE)

Correspondence Address: Patrick J. O'Shea;O'Shea, Getz & Kosakowski, P.C., Suite 912, 1500 Main Street, Springfield, MA, 01115, US

(21) Appl. No.: 10/951,343

(22) Filed: Sep. 27, 2004

(30) Foreign Application Priority Data
Sep. 25, 2003 (DE) 103 44 756.3

(51) Int. Cl. H03D 3/00

(52) U.S. Cl. 375/322

(57) ABSTRACT

The invention relates to a method and a circuit arrangement for deciding a symbol upon reception of a signal coupled with a quadrature signal pair, wherein the decision is made through analysis of the distance between at least one reception point and at least one nominal point in the complex space. In order to improve the pull-in regions or decision regions in the case of higher-quality modulation methods even in the region of larger radii, it is proposed that the distance be analyzed in the non-Cartesian or not exclusively Cartesian complex phase space, the complex signal being transformed for distance analysis in the preferably polar coordinate space (R, α) as non-Cartesian complex phase space.

### BACKGROUND OF THE INVENTION

The invention relates to an apparatus and method for deciding a symbol upon reception of a signal coupled with a quadrature signal.

Digital signals, also referred to as symbols, transmitted with the aid of cable-supported or wireless-supported communications systems represent a one-place or multi-place digital value in coded form. Coding for transmission is effected through the quadrature signal pair, which corresponds to a pointer that at certain points in time takes on discrete positions in the Cartesian amplitude and phase space of the quadrature signal pair. Usual transmission methods of this kind are QAM (quadrature amplitude modulation) and PSK (phase-shift keying).

In a usual receiver for the reception of digital signals, a complex multiplier or mixer driven by a local oscillator mixes the received QAM signal, modulated onto a carrier, into the base band of the circuit arrangement while preserving the frequency and phase. In digital processing, this can take place before or after A/D (analog-to-digital) conversion. The signal is sampled and digitized either with the symbol timing or a multiple thereof, or the digitizing timing is allowed to run free relative to the required symbol timing. In this case, the symbol is ultimately converted through a purely digital sampling rate change to the symbol timing or a multiple thereof. Gain controls make certain that the applicable dynamic range is exhausted and that the received symbols are correctly imaged to the symbol decider stage. An adaptive equalizer diminishes intersymbol interference, which has its origin in linear distortions of the transmitter, the transmission path, or the receiver.

In high-quality demodulators for QAM or PSK signals, the control circuits for frequency and phase control of the local oscillator, for gain control, for recovery of the symbol timing, and for the adaptive equalizer require both the received signals and also those elements of the specified symbol alphabet that are judged by a decider stage to be most probable. This kind of control using the decided symbol is referred to as “decision feedback” control and presupposes correct symbol decisions for correct control voltages.

Because the decision feedback controls in digital demodulators of the prior art are coupled to one another, latching is difficult if the control for the local oscillator, which mixes the received signal into the base band, is not yet stable in terms of frequency and phase. Latching often does not succeed unless the respective frequencies and phases lie relatively close to their nominal values.

Demodulators for QAM or PSK signals conventionally utilize a decision that assigns the received symbols according to the shortest distance to nominal symbols in the complex I/Q symbol plane. If the nominal symbols are arrayed on a uniform grid, a grid pattern arises for the decisions.

Such a procedure is optimal with respect to a signal with additive Gaussian noise but requires exact prior knowledge of the carrier frequency and carrier phase as well as the time of sampling. If the carrier phase, in particular in the case of higher-quality modulation methods, is only a few degrees away from the nominal phase, the symbols in the middle and outer range of radii are incorrectly decided. In the case of 256-QAM, a deviation as small as approximately 3 degrees is enough to lead to incorrect decisions. This effect is still stronger if there is a frequency offset with accumulating phase error, because a correct control voltage is generated only within a few angular degrees about a deviation of 0°, and also of 90°, 180°, and 270° if the quadrants are treated in modulo fashion.

The phase deviations between the received symbol and decided symbol are plotted for an angle deviation running from −45 to +45° in FIG. 12. The phase deviation in each case serves as control voltage for controlling the phase of the local oscillator. The distribution has a central diagonal passing from the negative quadrant through the origin into the positive quadrant. In the example depicted, with all individual decisions versus the angle deviation in a quadrant of 256-QAM, the distribution of the individual control voltages is such that it gives the correct mean control voltage, at least as to sign. The instantaneous control voltage, however, is often not correct.

FIG. 13 depicts a corresponding frequency distribution of control voltage versus angle deviation for 256-QAM in the complex plane, with the angle deviation running from −45° to +45°. The mean control voltage, that is, the sum by angle plotted versus the angle deviation for 256-QAM, can be inferred from FIG. 14. From both FIG. 13 and FIG. 14, it is easily recognized that correct individual decisions as to the control voltages will always be reached only in the central region. Erroneous individual decisions must be anticipated in the marginal regions.

EP 0571788 A2 discloses a carrier and phase control in which only the inner four symbols of the I/Q plane are employed, with additional hysteresis, in the framework of a reduced constellation. The frequency of these symbols in higher-quality modulation methods with uniform distribution, however, is at a very low level, for example only approximately 1.6% in the case of uniformly distributed 256-QAM.

U.S. Pat. No. 5,471,508 discloses a tracking mode by which the control initially works with a reduced modulation alphabet in the I/Q space, only large radii being taken into consideration.

In a method known from DE 199 28 206 A1, the complex I/Q plane is subdivided into smaller squares so that a more unambiguous mean control voltage can be obtained. This method, however, necessitates the use of large tables.

A method known from DE 41 00 099 C1 takes into consideration only the vertices of the I/Q modulation alphabet; in this way, again, many symbols get lost. What is more, a control is proposed that is too inexact for effective use.

EP 0249045 B1 (U.S. Pat. No. 4,811,363, DE 36 19 744 A1) proposes a method with a more comprehensive procedure in which a two-stage decision is performed. In a first step, a decision is made for a nominal radius; afterward, in a second step, the most probable nominal phase point on this decided nominal radius is assumed. Thus there is also known a partitioning of the complex plane with an orientation to the radii of circles on which the nominal symbols are arrayed, so that the bounds of the phase control in the radius direction are determined by annular sectors. These decision methods often lead to incorrect control voltages because the received symbols do not usually lie exactly at the nominal points. Such a method still functions in an acceptable fashion for phase constellations of 16-QAM. When a 64-QAM plane is considered, however, nine radii must be taken into account, some of which lie very close together as can be seen from FIG. 15. The nominal symbol positions of 64-QAM as well as the associated nine radii are depicted in the complex I/Q plane. In the positive quadrant, further, the boxes of a usual grid decision system are imaged. In addition, a pull-in region about the second radius is depicted in the form of a circular segment lying mostly inside one box but also intruding into adjacent boxes.

In 256-QAM, the radius bounds already lie so close together that adequately correct radius decisions can only be obtained very tentatively, particularly when additive noise is present. By way of illustration, FIG. 16 shows the distribution of the radii of a 256-QAM received signal. The transmitted radii are convoluted with Gaussian noise and plotted versus the radius R. The decision bounds for the nominal radii fall halfway between two nominal radii, which are depicted by dots. The portion of the distribution to which an incorrect nominal radius is assigned is shown with a negative sign. For an individual signal, the signal below a lower decision bound and above an upper decision bound would be assigned to an incorrect radius. The nominal radius decision depicted in FIG. 16 is integrated over all constellation points of one quadrant in 256-QAM. The radii here have up to four nominal symbols.

Experience indicates that in the case of such nominal radius decisions in 256-QAM, poor radius decisions predominate in the middle region in which the individual radii in the complex I/Q space lie very close together.

If an incorrect nominal radius has been decided in such a decision, the subsequent decision for a symbol at this radius must necessarily be incorrect as well. Thus the procedure described in what has gone before is inapplicable or only conditionally applicable for higher-quality modulation methods.

EP 0 281 652 discloses a method that forestalls a premature incorrect decision for a nominal radius in the following way: the first decision picks out not one nominal radius but a group of nominal radii that lie in a tolerance range about the radius of the received signal, before a decision for a phase is made in a second step from the set of all nominal phase values occurring at the selected nominal radii. There is no further evaluation of the distance between the received symbol and the selected symbol.

It is a goal of the invention to improve a method for deciding a symbol upon reception of a signal coupled with a quadrature signal pair and to furnish a corresponding circuit arrangement for implementation of such a method.

### SUMMARY OF THE INVENTION

The starting point is a method for deciding a symbol upon reception of a signal coupled with a quadrature signal pair, in which the decision is made through analysis of the distance from at least one reception point to at least one nominal point of the symbol in the complex space. The advantageous approach includes in distance being analyzed in the non-Cartesian or not exclusively Cartesian complex phase space and the decision is made in dependence thereon.

Instead of a pure box decision for a certain nominal symbol or a pure radius decision for a certain nominal radius followed by determination of the nominal phase, there is accordingly a combined procedure for the decision that simultaneously takes account of radial and phase-dependent aspects.

What is done in this procedure is thus not successively to determine, in a first step, particularly suitable radii for a received signal and then, in a subsequent step, to seek a suitable angle at this radius; instead, radius and angle are now considered simultaneously in a single decision by taking account of the distance between a reception point and a nominal point.

The analysis is advantageously carried out in the polar coordinate space, and so to this end the Cartesian phase space is transformed into a polar coordinate space. The decisions or a provisional decision then takes place in the polar coordinate space. In a combined consideration of quantities that depend on the radius component and/or the phase component, decision bounds can advantageously be flexibly adapted to the applicable requirements. Variables are defined for this purpose and then dynamically occupied in dependent fashion according to requirements.

The resulting larger tolerance with respect to phase errors is important particularly in decision feedback control in hunting mode, where reception frequency and reception phase have not yet been latched.

A combination of polar and Cartesian decisions offers good capabilities especially in the case of signals with additive noise.

In principle, other transformation methods can also be used in order to arrive at optimal decisions, depending on what coordinate system proves suitable for the objectives in view.

The examination and analysis of a Euclidean distance from the reception point to the possible nominal points serves in particular as a radius-dependent and phase-dependent criterion for decision. Here it is advantageous to introduce a factor to specify the weighting of radius errors and phase/angle errors relative to one another, in order to achieve optimal weighting in dependence on the signal state. The variable factor can advantageously be adapted to the prevailing reception conditions in dynamic fashion so that automation can be provided in dependence on the instantaneous reception conditions.

Additionally or alternatively, the sums of the radius projections and of the angle projections of the distance between the reception point and nominal points can also be analyzed. Here again, weighting with the aid of a dynamically adaptable factor is advantageous.

Particularly advantageous is a combination of such analyses and determinations from various coordinate systems, for example analysis on the one hand in the polar coordinate system and on the other hand in the Cartesian coordinate system, a joint evaluation being performed. Here again, a weighting factor can be used to advantage in order to permit dynamic adaptation to the reception conditions.

An auxiliary decider (slicer) can be employed to identify relevant nominal phase points to be tested.

A circuit arrangement for implementation of such a method essentially comprises the usual components of a receiver or decoder. After the conversion of the signal from the I/Q coordinate system to polar coordinates, symbol decision is performed next. Data originating in a minimization analysis of the various analyzable parameters, phase, radius, I coordinate and/or Q coordinate, are employed for this purpose.

Application of the method or of a corresponding circuit arrangement is a candidate procedure particularly in the case of binary or complex digital modulation methods such as QAM. Such modulation methods are utilized by the newer radio, television, and data services over cable, satellite, and land line.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 depicts a phase constellation of the first quadrant of 64-QAM, the phase being plotted versus the radius;

FIG. 2 and FIG. 3 depict phase constellations in the polar coordinate plane with variously chosen decision parameters;

FIG. 4 and FIG. 5 are mappings of the I/Q plane with decision grids, in each case with various minimization conditions dependent on radii and phases;

FIG. 6 and FIG. 7 are diagrams in the polar plane and the Cartesian plane respectively where, instead of the Euclidean distance in a correspondingly weighted R-α coordinate system being minimized, the sum of correspondingly weighted radius and angle projections is minimized;

FIG. 8 shows a comparison of mean control voltages between a decision in the polar coordinate space and a conventional manner of decision;

FIG. 9 is a diagram in the Cartesian coordinate system with combined polar and Cartesian decision criteria;

FIG. 10 is a diagram with decision criteria as in FIG. 6 and FIG. 7 in which the set of nominal points to be taken into account for the decision has been restricted;

FIG. 11 is a circuit diagram for a decoder for deciding a symbol;

FIG. 12 to FIG. 14 depict control voltages plotted versus angle deviation according to the prior art in various modes of representation;

FIG. 15 depicts the complex I/Q plane with symbol positions as well as boxes and radii for symbol decision according to the prior art; and

FIG. 16 depicts the result of a corresponding nominal radius decision over all the constellation points of a quadrant in the case of a 256-QAM with Gaussian noise superimposed.

### DETAILED DESCRIPTION OF THE INVENTION

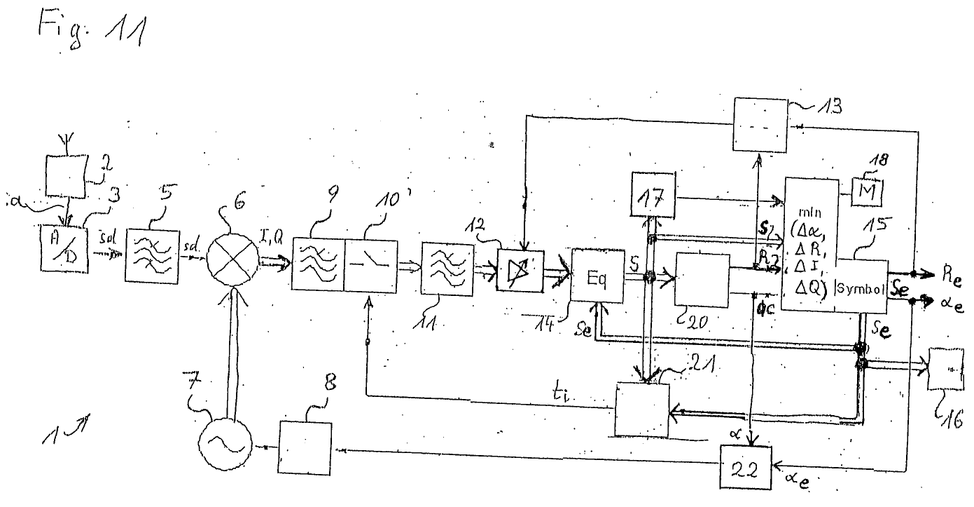

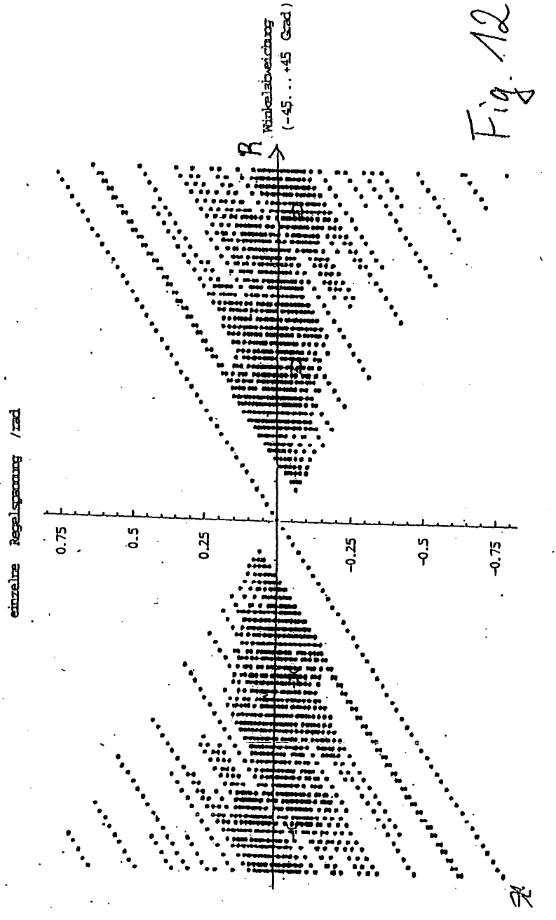

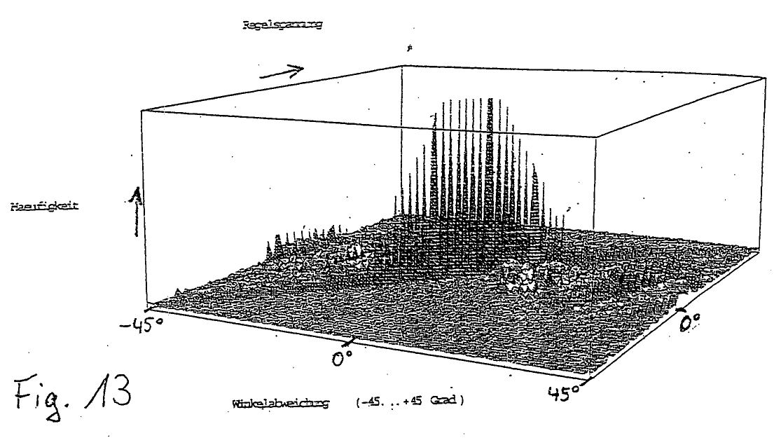

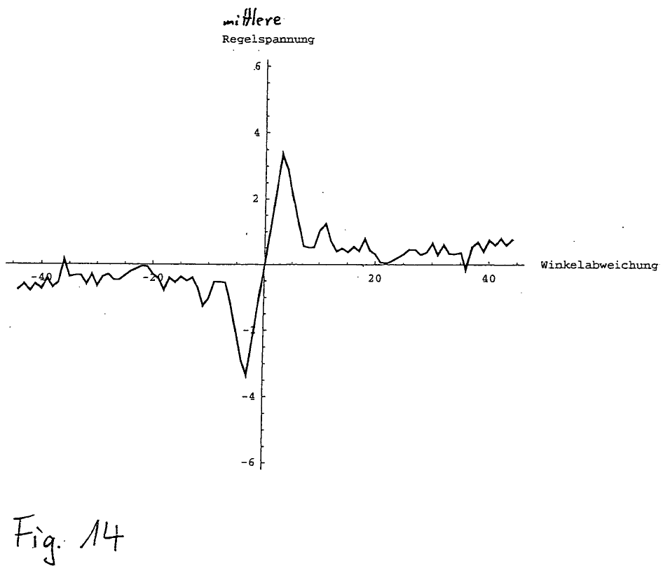

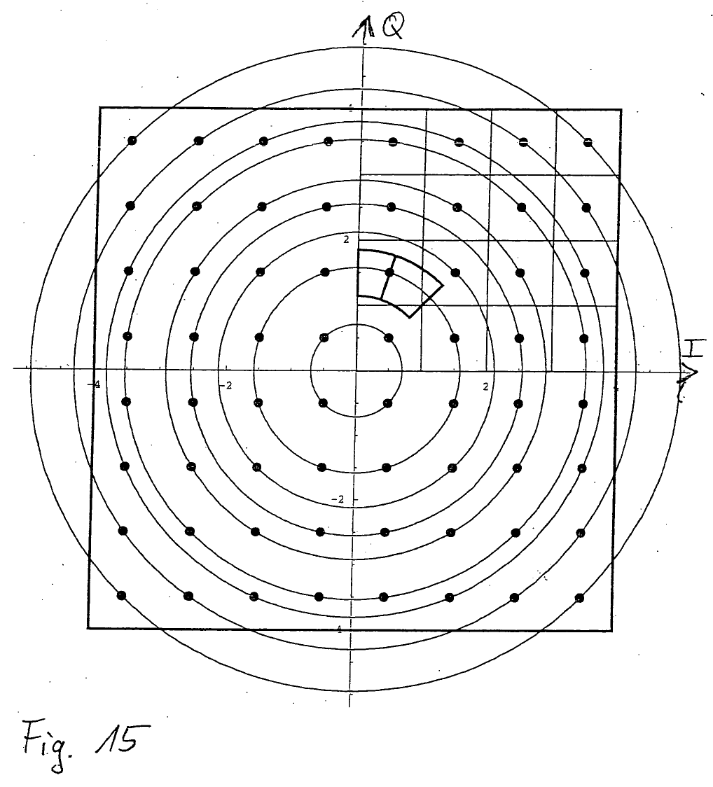

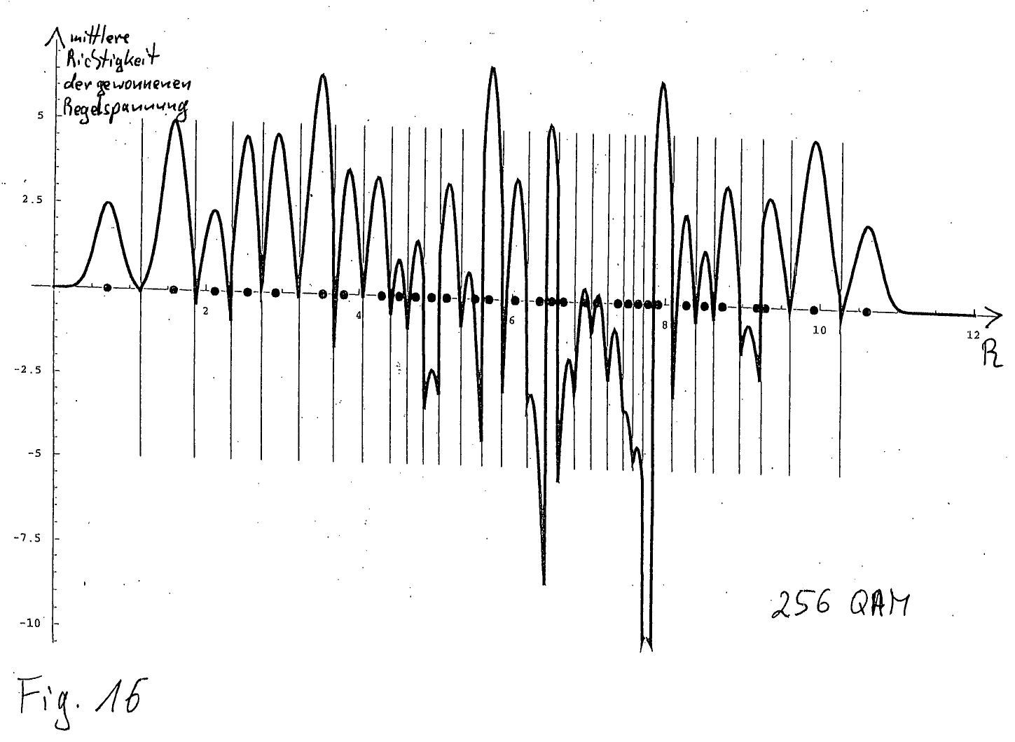

As can be seen from FIG. 11, a demodulator 1, as an exemplary circuit arrangement for the determination and decision of symbols S from a digitized signal sd that is coupled to a quadrature signal pair of a modulation method, for example according to a QAM standard, comprises a plurality of individual components. These can all or individually be constituents of an integrated circuit as well. In particular, components described in what follows can, according to the application objective, be omitted or supplemented by further components. The forwarding of signals as real signals, complex signals, or individual complex signal components is also adaptable as appropriate to the application objective and the particular circuit arrangement.

In the embodiment depicted, demodulator 1 receives at an input an analog signal sa from a signal source 2, for example a tuner. This analog signal sa, which usually exists in a band-limited intermediate frequency position, is supplied to an A/D (analog-to-digital) converter 3 for conversion to a digital signal sd. For the case where the further circuit components are to have no symbol sampling mechanism, A/D converter 3 has an input for a timing signal or sampling signal tᵢ. Digital signal sd is led from A/D converter 3 to a bandpass filter 5, which removes dc components and interfering harmonics from the digital signal.

The signal output from bandpass filter 5 is supplied to a quadrature converter 6, which converts digital or digitized signal sd into the base band. The base band corresponds to the requirements of demodulator 1 and of the modulation method employed. Accordingly, the quadrature converter outputs digitized signal sd split into two quadrature signal components I, Q of the Cartesian coordinate system. For frequency conversion, quadrature converter 6 is usually fed with two carriers offset by 90° from a local oscillator 7 whose frequency and phase are controlled by a carrier controller 8.

Quadrature signal components I, Q output by quadrature converter 6 are supplied to a low-pass filter 9, which removes interfering harmonics. Low-pass filter 9 and a symbol sampler 10 connected after it form a circuit for changing the sampling rate. Symbol sampler 10 advantageously has a sampling controller integrated or connected ahead of it. Symbol sampler 10 is controlled through an input to which sampling signal tᵢ is supplied by a timing controller 21. In the normal operating state, symbol sampling times tᵢ are dictated by the symbol rate 1/T of the modulation method employed or a whole-number multiple thereof and by the exact phase position of the received symbols.

The output signal of sampler 10 is filtered by a low-pass filter 11 with a Nyquist characteristic and supplied to a gain controller 12. Gain controller 12 serves to cover the dynamic range of a provisional decider 17 and a symbol decider 15 in calibrated fashion.

The output signal of gain controller 12 is supplied to an equalizer 14.

Alternatively, a self-controlling gain controller can be used, the self-contained amplitude controller 13 in particular then being dispensable. Equalizer 14 removes interfering distortions from components I, Q of the quadrature signal pair and furnishes at its output a provisional complex symbol S. A coordinate converter, in the present case a quadrature converter 20, connected next in series converts complex symbol S from the Cartesian to the polar coordinate system; that is, a polar value pair R, α is formed from a sampled quadrature signal pair I, Q.

Thus, with the polar coordinates, a radius component R and an angle component α described by I=R·cos(α) and Q=R·sin(α) and satisfying the relations R=\sqrt{(I²+Q²)} and α=arctan(Q/I) are formed. Provisional symbol S now exists in both Cartesian and polar coordinates. Alternatively, coordinate converters of a different kind can also be employed.

Digital signal processing often achieves coordinate transformation by the so-called Cordic method, which employs only additions and multiplications by two, operations that can be implemented by simple positional shifts in the case of binary numbers. Alternatively, other approximation methods or the use of tables is also possible. The inverse conversion, that is, conversion from polar signal components R and α to their quadrature components I and Q respectively, can likewise be accomplished with a Cordic converter, a table, or an approximation method.

While a circuit arrangement with a converter 6 for converting the digital signal into the complex Cartesian space I, Q and a converter 20 for conversion to polar coordinates has been described, circuit arrangements in which the first converter itself converts digital signal sd into a complex signal with polar coordinates R, α are also possible.

From provisional symbols furnished in this fashion, so-called decided symbols Se are formed by symbol decider 15, which decided symbols can in particular exist in both Cartesian and polar coordinates. A storage unit M connected to one more of the circuit devices is expediently used to store the values.

These symbols S, Se, and/or their radius components Rₑ or αₑ are then supplied directly or indirectly to further digital signal processors 16 and preferably also to decision feedback control circuits or components in demodulator 1. In particular, equalizer 14 is given symbol Se, carrier controller 8 is given a control signal derived from the difference between the received nominal phase α and decided nominal phase αₑ in a control circuit 22, gain controller 12 is given a control signal derived from the difference between the received radius R and decided radius Rₑ in an amplitude controller 13, and sampler 10 is given a sampling signal tᵢ derived from a comparison between the received symbol string and the decided symbol string in timing controller 21.

For the control of timing controller 21, carrier control circuit 13 and amplitude control circuit 22, and further components of demodulator 1, these are connected to a controller. The controller brings about an orderly sequence and controls the individual components and processes in accordance with hardware-supported or software-supported instructions. The controller can preferably also have functions of individual ones of the said components wholly or partly integrated into it.

In contrast to the usual symbol determination with the aid of symbol decider 15 in the Cartesian complex coordinate space I, Q, symbol decision in the present case is performed by symbol decider 15 in the non-Cartesian complex coordinate space or not completely in the Cartesian complex coordinate space.

In what follows, the decision made by decision device 15 is explained in illustrative fashion with reference to a multiplicity of diagrams. The goal here is a simultaneous examination of quantities that depend on the radius R, the angle α, and/or the Cartesian coordinates I and Q. Decision device 15 is advantageously connected to a storage M in which, among other things, comparison data are stored.

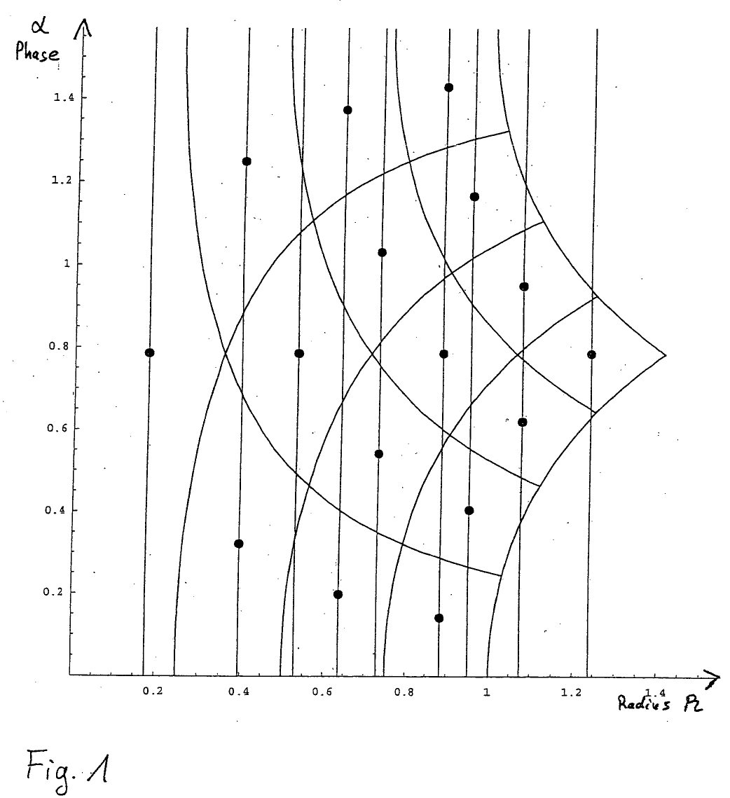

As can be seen from FIG. 1, the decision boxes or decision radii become distorted when the symbols are transformed from the Cartesian I/Q coordinate system to a polar coordinate system with the variables R and α and plotted in right-angle fashion. What is imaged is the phase constellation of the first quadrant of 64-QAM. Here the phase is plotted versus the radius, the vertical lines representing the nominal radii and the drawn-in hyperbolas representing the decision grid of the Cartesian I/Q system. Decisions, that is, assignments of the received signal S(R,α) to a nominal signal point Se(R,α), can now be performed in this distorted form of representation.

Because of the fundamentally unlike character of the two variables radius R and phase α, additional processing is expedient here.

The first question to be considered is in what relationship the two coordinates R, α stand, a merely arbitrarily plotted division of the axes being sketched in FIG. 1. For the calculations that follow, the radius is calibrated in such a way that the lengths of both sides of the box containing all phase points is 1 in each instance, so that the vertex falls at a value of \sqrt{2} and the angular extent of a quadrant is π/2.

The second point to be considered is how the distance function is to be defined in the polar coordinate plane R, α.

From FIG. 1 it can already be recognized that relatively large pull-in regions about the nominal positions can be assigned to some symbol positions, each in comparison to the other determination systems.

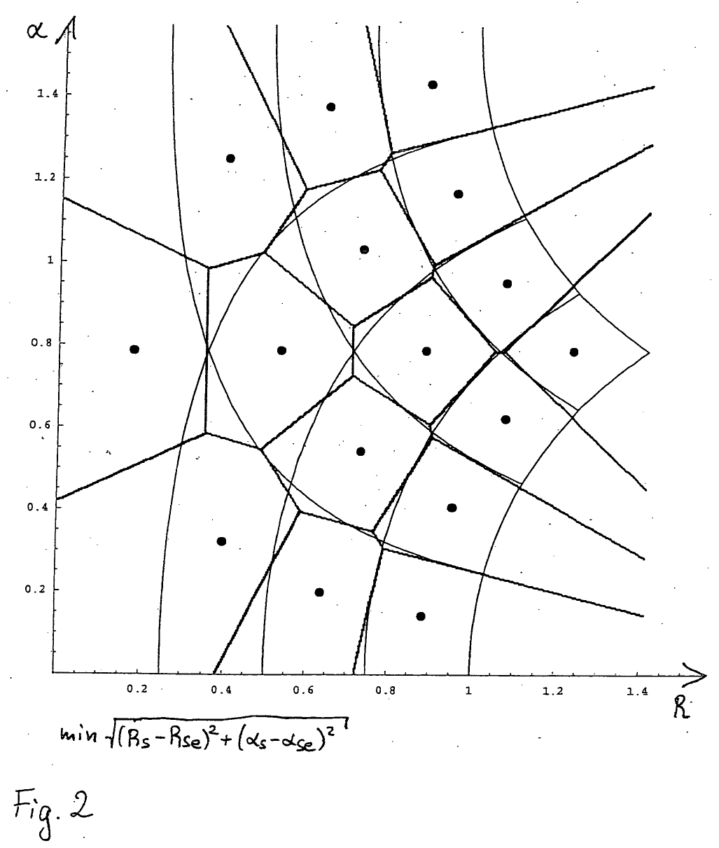

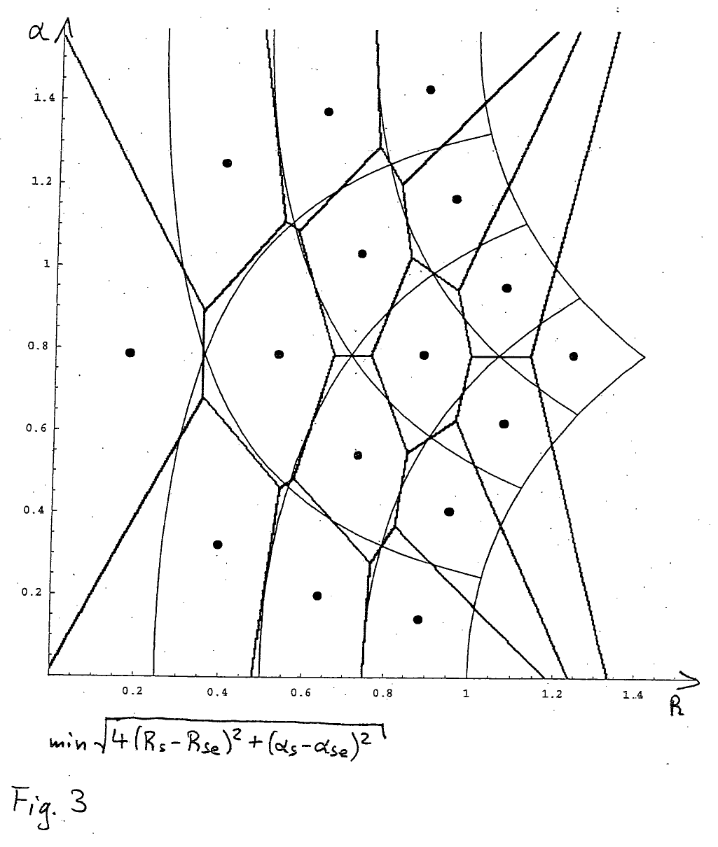

In order to effect a further optimization of the examination system, the Euclidean distance between the received symbols S(R,α) and the nominal symbols Sₑ(R,α) can be minimized. Examples of such decision grids for 64-QAM are depicted in FIG. 2 and FIG. 3 for the first quadrant of a polar plane R, α. Here FIG. 2 shows the polar plane R, α with a decision grid based on minimization according to min(√(R_{S}−R_{Se})²+(α_{S}−α_{Se})²)) (where denotes “the square root of”). Relatively large cells result for the region with small radii, while the cell sizes decrease for larger radii.

The introduction of multipliers u, w makes it possible to allot unequal weights to the radius fields and angle fields according to min((\sqrt{2}u·(R_{S}−R_{Se})²+(α_{S}−α_{Se})²)). Because the issue is merely the determination of the minimum and not of absolute values, an appropriately selected factor u is sufficient. For the subsequent analysis, w is therefore chosen equal to 1.

FIG. 3 shows the situation upon examining the minimization of the Euclidean distance using a radius factor u with u=4, which thus allots a greater weight to the radius contribution than to the angle contribution according to the formula min(SQRT(u·(R_{S}−R_{Se})²+(α_{S}−α_{Se})²)). This leads to stretching the decision regions in the direction of the angle quantity α.

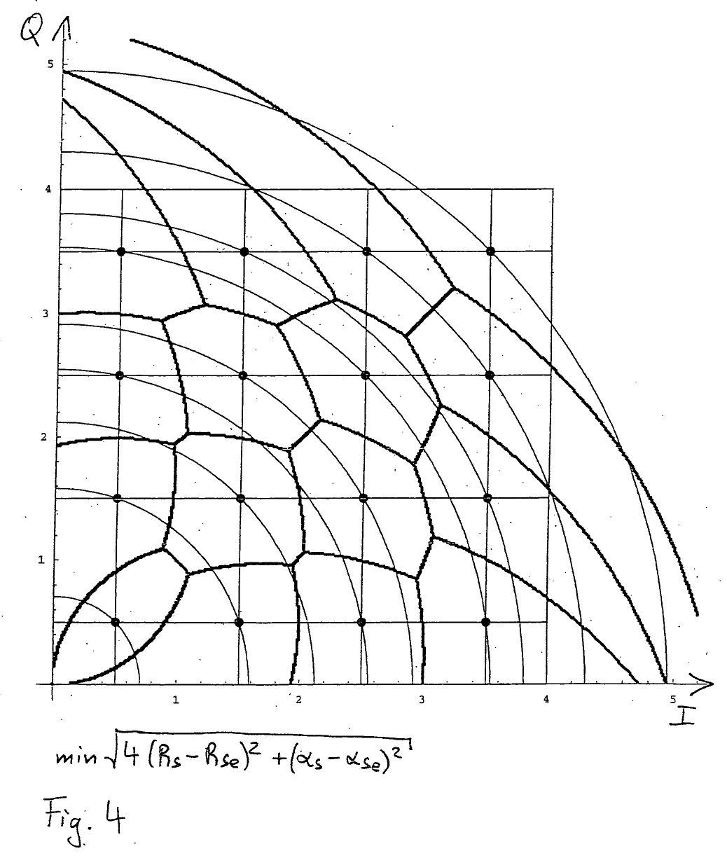

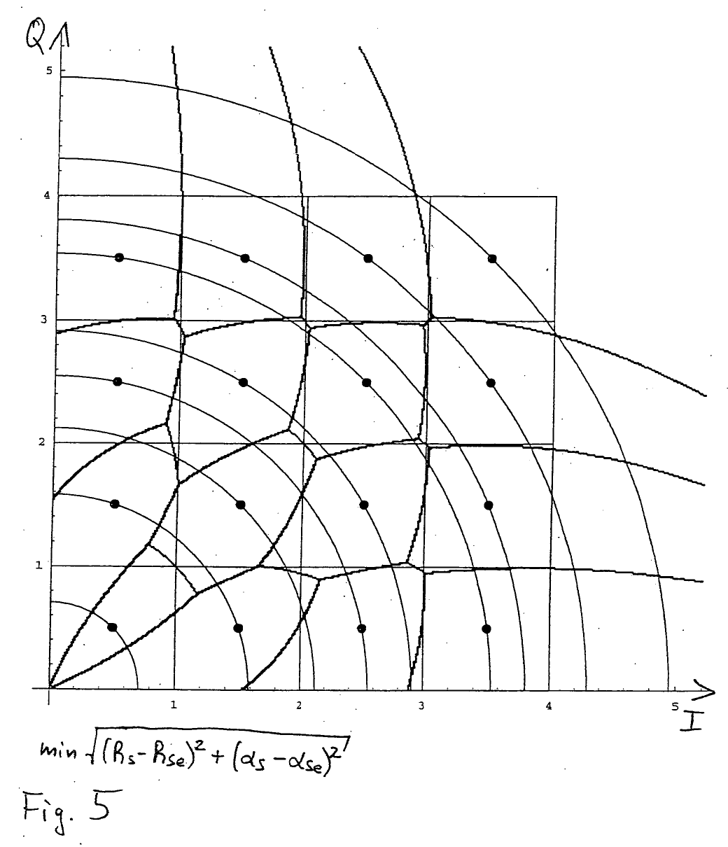

An inverse transformation of the decision grid of the first quadrant with the factor u=4 from FIG. 3 into the Cartesian plane I/Q is depicted in FIG. 4. Although the decision fields already become relatively narrow in the middle range of radii, the bounds intersect in the outer region of the outermost radius, which is undesirable. In the determination of the Euclidean distance without a multiplier or with u=1 according to FIG. 2, the outer regions thus fan out further, as can be seen from FIG. 5.

Alternatively, a minimization decision can also be employed that uses for example the sum of the projections on R and α instead of the Euclidean distance, that is, a procedure according to min(u|R_{S}−R_{Sw}|+|α_{S}−α_{Se}|).

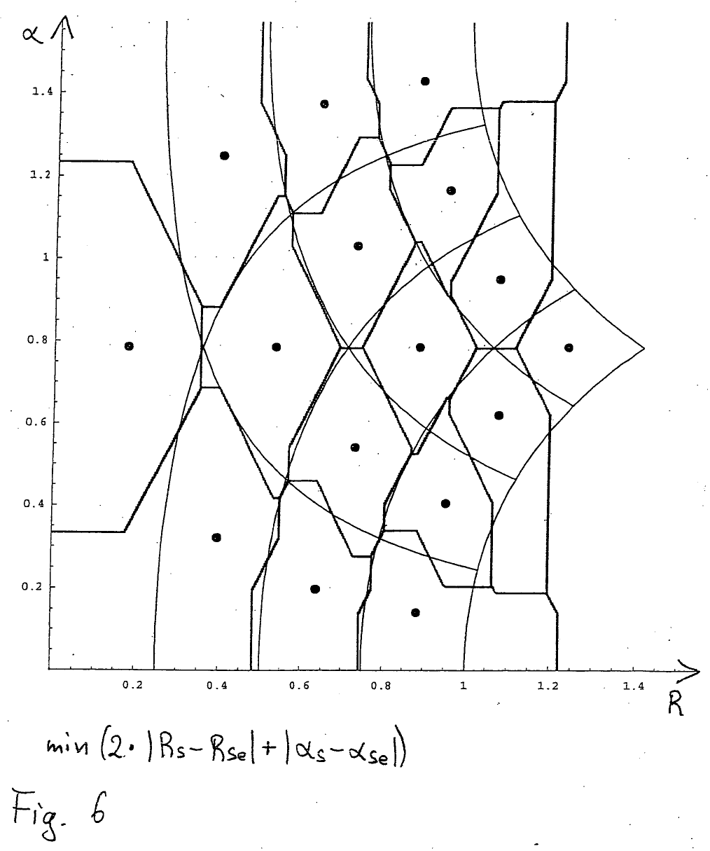

As can be seen from FIG. 6, which shows the polar coordinate plane R, α with a decision grid with the radius factor u=2 for the radius component, the subdivision into cells or the subdivision of the pull-in regions is more advantageous than was the case when the pure Euclidean distances themselves were considered with the greater radius weighting of u=4.

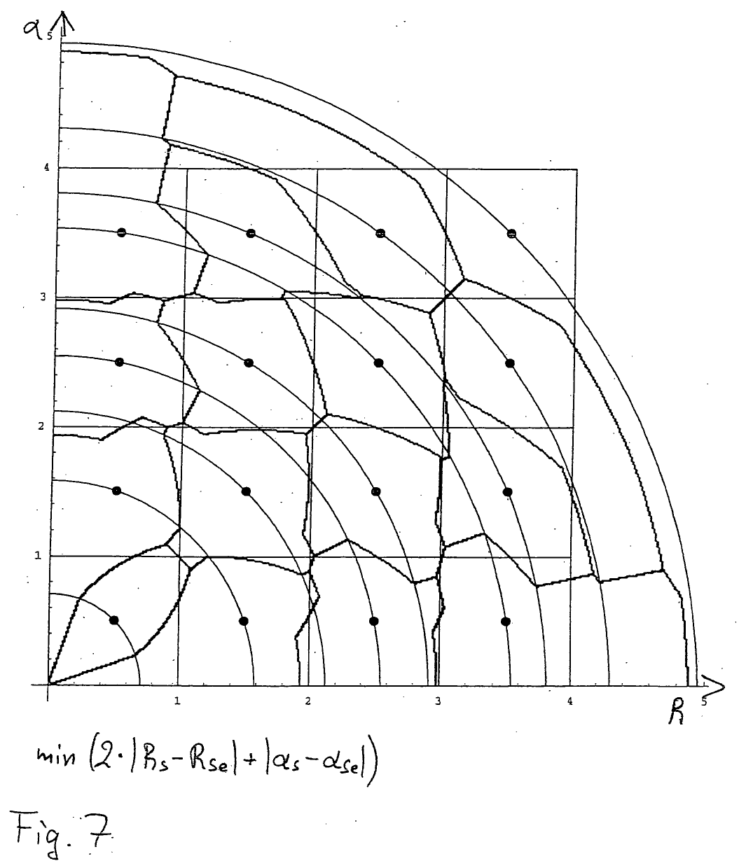

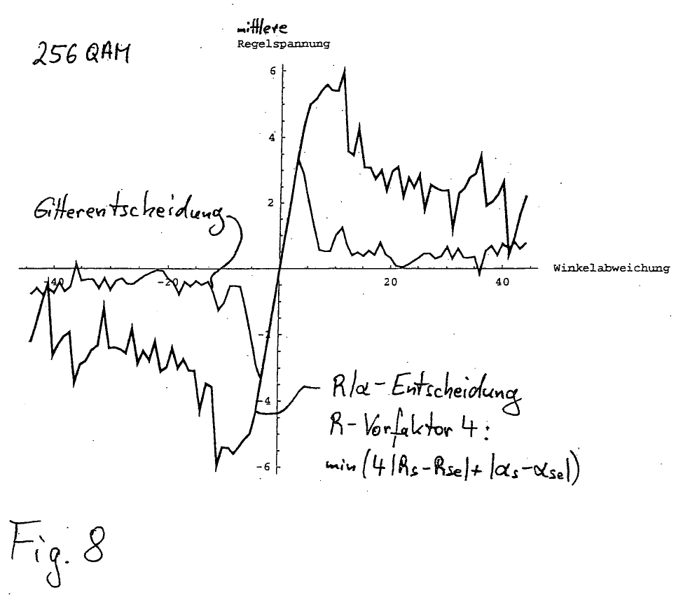

FIG. 7 shows the inverse transformation of the decision grid from FIG. 6 in the corresponding I/Q coordinate plane. In the case of this minimization, the radius bounds come out correctly in the outer region, while a modified grid decision procedure is present in the central region. As can be seen from the plot of the mean control voltage in 256-QAM according to FIG. 8, the function of the mean phase control voltage is substantially better than for a pure grid decision according to the prior art. Here a minimization function with the sum of the projections and the radius multiplier u=4, analogously to FIG. 6 and FIG. 7, was employed.

Because the radius component R_{S} and the angle component α_{S} exist as results from coordinate converter 20 and the radius component R_{Se} and the angle component α_{Se} for the nominal symbols exist in tables in storage M, such a minimum determination can be carried out relatively easily through simple comparisons. The decision can be adapted during operation to instantaneous circumstances, for example high phase jitter or severe noise, by simply changing the multiplier, in particular radius multiplier u.

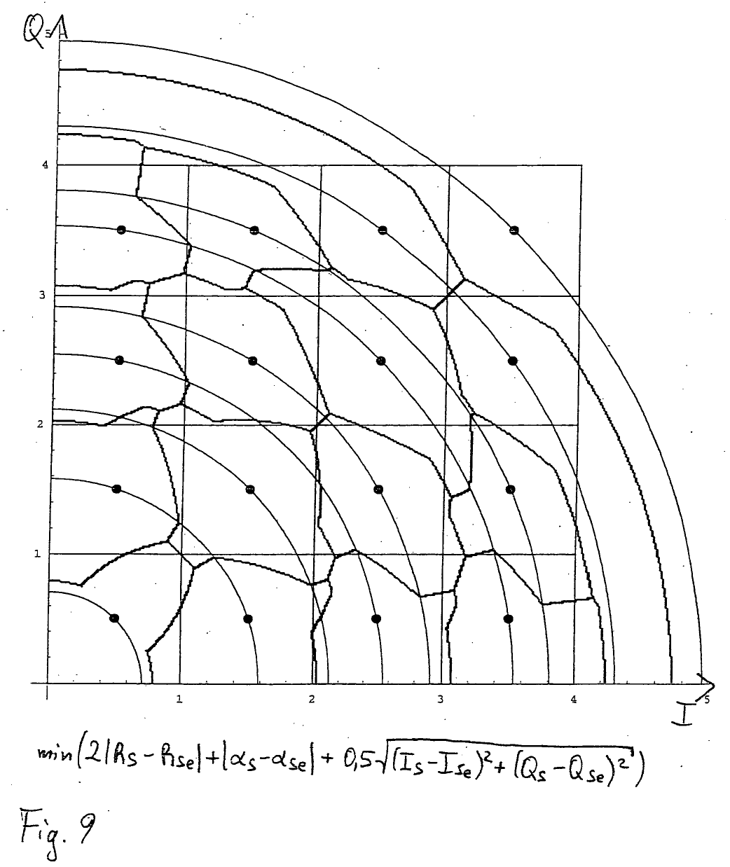

Striking in FIG. 7 is a curvature of the decision bounds for the pull-in regions corresponding to the innermost symbol. This curvature arises from the large angle deviation that governs the decision at the edges of the quadrant. This effect can be diminished, however, by appending a term in the minimum decision to represent the distances in the Cartesian complex I/Q plane. All decision fields or pull-in fields about the nominal phase points of the nominal symbols Sₑ can be enlarged by combining the two minimization methods, as can be seen from FIG. 9. FIG. 9 shows the Cartesian I/Q plane with a decision grid according to min(u|R_{S}−R_{Se}|+|α_{S}−α_{Se}|+v{square root over (((I_{E}−I_{S})²+(Q_{E}−Q_{S})²))} with multipliers u=4 and v=0.5 for coordinate system selection. Arbitrary and dynamically alterable combinations can be set up in this mode of analysis.

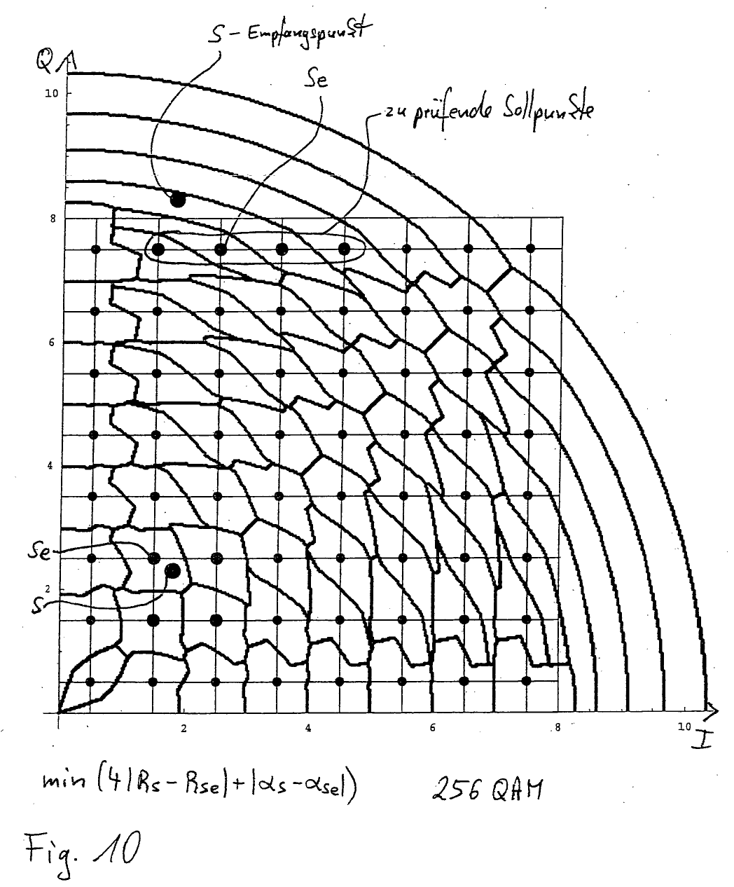

The number of nominal symbols Se to be tested can be suitably diminished in order to reduce the effort involved in the minimum calculation. For example, the square bounded by four symbols in which the reception point lies can first be determined by a decider or slicer 17 in the Cartesian system with a one-half symbol offset. Only the minimum distance to these four nominal points is then calculated. If the reception point lies outside the nominal fields, then in the minimum determination it is necessary to test the four marginal nominal points of which two lie nearest the reception point in the Cartesian space and two have a larger radius. Such a situation for 256-QAM can be inferred from FIG. 10, in which two reception points S and, for each, four correspondingly assigned nominal points Sₑ can be inferred. The right-angle grid in the I/Q plane in FIG. 10 specifies the four nominal points to be tested for each of the two reception examples, before the minimum determination min(u|R_{S}−R_{Se}|+|α_{S}−α_{Se}|) with u=4 is performed for each of these four points.

Although the present invention has been shown and described with respect to several preferred embodiments thereof, various changes, omissions and additions to the form and detail thereof, may be made therein, without departing from the spirit and scope of the invention.

1. A method for deciding a symbol (Se) upon reception of a signal (s) coupled with a quadrature signal pair (I, Q) wherein
the decision is made through analysis of the distance (D) from at least one reception point (S) to at least one nominal point (Se) in the complex coordinate space (I, Q), characterized in that
the distance (D) is analyzed in the non-Cartesian or not exclusively Cartesian complex coordinate space and the decision is made thereupon.

2. Method according to claim 1 wherein the distance (D) is analyzed in the polar coordinate space (R, α).

3. Method according to claim 2 wherein
the Cartesian coordinate space (I, Q) is transformed to the polar coordinate space (R, α),
the analysis of the distances (D) is carried out in the polar coordinate space, and
an inverse transformation to the Cartesian space (I, Q) is performed.

4. Method according to claim 1 wherein the Euclidean distance between the reception points and nominal points is analyzed as distance (D) in the non-Cartesian coordinate space, in particular according to min(SQRT(u·(R_{S}−R_{Se})²+(α_{S}−α_{Se})²)).

5. Method according to claim 1 wherein the sum of the angle and radius projections of the distance between the reception point and at least one nominal point is analyzed in the non-Cartesian coordinate system, in particular according to min(u|R_{S}−R_{Se}|+|α_{S}−α_{Se}|).

6. Method according to claim 4 wherein, for the analysis of the distance, a weight factor (u) for the weighting of a radius error and/or a weight factor (w) for the weighting of an angle error is employed for the weighting of the radius error and phase error in relation to one another.

7. Method according to claim 6 wherein the weight factor or weight factors (u, w) are dynamically adapted to the reception conditions of the signal (s).

8. Method according to claims 4 wherein a combination of unlike minimization methods are performed in order to determine the distance in the non-Cartesian space, in particular a combination of the determination of a Euclidean distance from the reception point to at least one nominal point on the one hand and, on the other hand, the determination of the sum of the angle and radius projections of the distance between the reception point and at least the one nominal point is analyzed, in particular according to \sqrt{u(R_{S}−R_{Se})²+w(α_{S}−α_{Se})²}+\sqrt{(I_{S}−I_{Se})²+(Q_{S}−Q_{Se})²}

9. Method according to claim 1, wherein for the analysis of the distance (D), a combination of methods for minimizing the distance between a reception point and at least one nominal point is performed by, on the one hand, at least one method for minimization in the non-Cartesian space and, on the other hand, one method for minimizing the distance in the Cartesian space, in particular according to min(u|R_{S}−R_{Se}|+w|α_{S}−α_{Se}|+v^{{square root over ((I_{S}^{−I}_{Se}⁾²^{+(Q}_{S}^{−Q}_{Se}⁾²)}.}

10. Method according to claim 9 wherein a weight factor (v) is defined for the weighting of the effect of the determination in the Cartesian space in relation to the determination in the non-Cartesian space.

11. A circuit arrangement for deciding a symbol (S) upon reception of a signal (s) coupled with a quadrature signal pair (I, Q),
having
a coordinate converter (20) for converting the signal from Cartesian coordinates (I, Q) to non-Cartesian coordinates (R, α),
a provisional decider (17) for determining a minimal distance between a reception point (S) and at least one corresponding nominal point (Se) on the basis of the Cartesian signal,
a decider (15) for deciding a signal on the basis of the distance analysis, and
a controller for controlling the circuit arrangement and a process sequence, in particular a processing sequence according to one of the foregoing claims.
